(19) United States
(12) Patent Application Publication
(10) Pub. No.: US 2022/0093029 A1
(43) Pub. Date: Mar. 24, 2022

(54) GATE DRIVER AND DISPLAY DEVICE INCLUDING THE SAME

(71) Applicant: Samsung Display Co., Ltd., Yongin-si (KR)

(72) Inventors: Jaemin SEONG, Suwon-si (KR); Kangnam KIM, Seoul (KR); Jae-Hyun PARK, Yongin-si (KR); Hyunwook LEE, Asan-si (KR)

(21) Appl. No.: 17/544,862

(22) Filed: Dec. 7, 2021

Related U.S. Application Data
(63) Continuation of application No. 16/268,995, filed on Feb. 6, 2019.

(30) Foreign Application Priority Data
Feb. 26, 2018 (KR) 10-2018-0022749

(51) Int. Cl. G09G 3/20; G09G 3/3266; G09G 3/36; G11C 19/28

(52) U.S. Cl. CPC G09G 3/20; G09G 3/3266; G09G 3/3674; G11C 19/28; G09G 2310/0286; G09G 2310/08; G09G 2300/0809; G09G 2300/0426; G09G 2340/0442; G09G 3/3677

(57) ABSTRACT

A gate driver includes stages each including a first-transistor including a gate-electrode receiving an output-signal of one previous-stage or a vertical-start-signal as a first input-signal, a first-electrode receiving the first input-signal, and a second-electrode connected to a first-node, a second-transistor including a gate-electrode connected to the first-node, a first-electrode receiving a first clock-signal, and a second-electrode connected to a first-output-terminal, a third-transistor including a gate-electrode receiving a second clock-signal, a first-electrode receiving a first power-voltage, and a second-electrode connected to the first-output-terminal, a fourth-transistor including a gate-electrode receiving a third clock-signal, a first-electrode receiving the third clock-signal, and a second-electrode connected to a second-node, a fifth-transistor including a gate-electrode connected to the second-node, a first-electrode receiving a second power-voltage, and a second-electrode connected to the first-node, and a sixth-transistor including a gate-electrode connected to the first-node, a first-electrode receiving the second power-voltage, and a second-electrode connected to the second-node.

### CROSS-REFERENCE TO RELATED APPLICATIONS

This application is a continuation of U.S. application Ser. No. 16/268, 995 filed Feb. 6, 2019, which claims priority to and the benefit of Korean Patent Application No. 10-2018-0022749, filed on Feb. 26, 2018 in the Korean Intellectual Property Office (KIPO), the entire contents of all of which are incorporated herein by reference.

### BACKGROUND

### 1. Field

Aspects of some example embodiments relate generally to a display device.

### 2. Description of the Related Art

Generally, a display device includes a display panel and a panel driver. The display panel includes a plurality of gate-lines, a plurality of data-lines, and a plurality of pixels. The panel driver includes a gate driver that provides a gate signal to the gate-lines and a data driver that provides a data signal to the data-lines.

The gate driver includes a plurality of stages that provide the gate signal to the gate-lines. Each of the stages includes a plurality of transistors and a capacitor. The gate driver may be formed (e.g., patterned) on a substrate on which the display panel including the pixels is formed (e.g., patterned). Because the gate driver corresponds to a non-display region on which an image is not displayed, many manufacturers tries to reduce an integrated area of the gate driver to satisfy a consumer's demand for an appearance of an electronic device.

When a voltage level of a driving power applied to the gate driver is increased to drive a large-area display device, threshold voltages of transistors may be changed as time passes, and thus a leakage current may be caused. When the leakage current of the stage is caused by the transistors, voltages at nodes of the stage may not be maintained constant. Thus, a ripple may be caused in the gate signal, or an abnormal gate signal may be output.

The above information disclosed in this Background section is only for enhancement of understanding of the background of the invention and therefore it may contain information that does not constitute prior art.

### SUMMARY

Aspects of some example embodiments relate generally to a display device. For example, some example embodiments of the present inventive concept relate to a gate driver and a display device including the gate driver.

Some example embodiments include a gate driver that may achieve high reliability while being implemented with a relatively simple structure (e.g., simple circuit).

Some example embodiments include a display device including the gate driver.

According to an aspect of some example embodiments, a gate driver may include a plurality of stages each outputting an output signal. Here, each of the stages may include a first transistor including a gate electrode which receives an output signal of one of previous stages or a vertical start signal as a first input signal, a first electrode which receives the first input signal, and a second electrode which is connected to a first node, a second transistor including a gate electrode which is connected to the first node, a first electrode which receives a first clock signal, and a second electrode which is connected to a first output terminal, a third transistor including a gate electrode which receives a second clock signal, a first electrode which receives a first power voltage, and a second electrode which is connected to the first output terminal, a fourth transistor including a gate electrode which receives a third clock signal, a first electrode which receives the third clock signal, and a second electrode which is connected to a second node, a fifth transistor including a gate electrode which is connected to the second node, a first electrode which receives a second power voltage, and a second electrode which is connected to the first node, and a sixth transistor including a gate electrode which is connected to the first node, a first electrode which receives the second power voltage, and a second electrode which is connected to the second node.

In some example embodiments, the each of the stages may further include a seventh transistor including a gate electrode which receives an output signal of one of next stages as a second input signal, a first electrode which receives the second power voltage, and a second electrode which is connected to the first node.

In some example embodiments, the output signal of the one of the next stages may be a signal which is obtained by shifting the output signal of the each of the stages by 3/2 of one horizontal period.

In some example embodiments, a first aspect ratio of the sixth transistor may be larger than a second aspect ratio of the fourth transistor.

In some example embodiments, the each of the stages may further include a first capacitor connected between the gate electrode of the second transistor and the second electrode of the second transistor.

In some example embodiments, the first clock signal may be an inverted version of the second clock signal.

In some example embodiments, the third clock signal may be a signal which is obtained by shifting the second clock signal by ½ of one horizontal period.

In some example embodiments, the output signal of the each of the stages may be a signal which is obtained by shifting the output signal of the one of the previous stages by one horizontal period.

In some example embodiments, the first power voltage may be higher than the second power voltage.

In some example embodiments, the first power voltage may be equal to the second power voltage.

In some example embodiments, the each of the stages may further include an eighth transistor including a gate electrode which is connected to the first node, a first electrode which receives the first clock signal, and a second electrode which is connected to a second output terminal, and a ninth transistor including a gate electrode which receives the second clock signal, a first electrode which receives the second power voltage, and a second electrode which is connected to the second output terminal.

According to another aspect of some example embodiments, a gate driver may include a plurality of stages each outputting an output signal. Here, each of the stages may include a first node controlling unit configured to receive an output signal of one of previous stages or a vertical start signal as a first input signal and to apply the first input signal to a first node based on the first input signal, a first outputting unit configured to apply a first clock signal to a first output terminal based on a voltage at the first node, a second outputting unit configured to apply a first power voltage to the first output terminal based on a second clock signal, a second node controlling unit configured to apply a third clock signal to a second node based on the third clock signal, a first holding unit configured to apply a second power voltage to the first node based on a voltage at the second node, and a third node controlling unit configured to apply the second power voltage to the second node based on the voltage at the first node.

In some example embodiments, the each of the stages may further include a second holding unit configured to receive an output signal of one of next stages as a second input signal and to apply the second power voltage to the first node based on the second input signal.

In some example embodiments, the output signal of the one of the next stages may be a signal which is obtained by shifting the output signal of the each of the stages by 3/2 of one horizontal period.

In some example embodiments, a first aspect ratio of a transistor included in the third node controlling unit may be larger than a second aspect ratio of a transistor included in the second node controlling unit.

In some example embodiments, the each of the stages may further include a first carry outputting unit configured to apply the first clock signal to a second output terminal based on the voltage at the first node, and a second carry outputting unit configured to apply the second power voltage to the second output terminal based on the second clock signal.

According to an aspect of some example embodiments, a display device may include a display panel including a plurality of gate-lines, a plurality of data-lines, and a plurality of pixels, a data driver configured to provide a data signal to the pixels via the data-lines, and a gate driver configured to provide a gate signal to the pixels via the gate-lines, the gate driver including a plurality of stages each outputting the gate signal as an output signal. Here, each of the stages may include a first transistor including a gate electrode which receives an output signal of one of previous stages or a vertical start signal as a first input signal, a first electrode which receives the first input signal, and a second electrode which is connected to a first node, a second transistor including a gate electrode which is connected to the first node, a first electrode which receives a first clock signal, and a second electrode which is connected to a first output terminal, a third transistor including a gate electrode which receives a second clock signal, a first electrode which receives a first power voltage, and a second electrode which is connected to the first output terminal, a fourth transistor including a gate electrode which receives a third clock signal, a first electrode which receives the third clock signal, and a second electrode which is connected to a second node, a fifth transistor including a gate electrode which is connected to the second node, a first electrode which receives a second power voltage, and a second electrode which is connected to the first node, and a sixth transistor including a gate electrode which is connected to the first node, a first electrode which receives the second power voltage, and a second electrode which is connected to the second node.

In some example embodiments, the each of the stages may further include a seventh transistor including a gate electrode which receives an output signal of one of next stages as a second input signal, a first electrode which receives the second power voltage, and a second electrode which is connected to the first node.

In some example embodiments, the output signal of the one of the next stages may be a signal which is obtained by shifting the output signal of the each of the stages by 3/2 of one horizontal period.

In some example embodiments, a first aspect ratio of the sixth transistor may be larger than a second aspect ratio of the fourth transistor.

Therefore, a gate driver according to some example embodiments may be implemented with a simple circuit in which a fifth transistor which holds a first node is controlled based on a voltage at a second node and the voltage at the second node is controlled by a fourth transistor and a sixth transistor based on a third clock signal and a voltage at the first node, respectively. The gate driver may prevent or reduce a leakage current by separating a first power voltage and a second power voltage. The gate driver may reduce deterioration of fifth and seventh transistors by including the seventh transistor which is controlled based on a second input signal.

In addition, a display device according to some example embodiments may operate stably by including the gate driver having improved reliability. The display device may reduce an area (or size) of a non-display region by including the gate driver which is implemented with a simple circuit.

### BRIEF DESCRIPTION OF THE DRAWINGS

Illustrative, non-limiting example embodiments will be more clearly understood from the following detailed description in conjunction with the accompanying drawings.

FIG. 1 is a block diagram illustrating a display device according to some example embodiments.

FIG. 2 is a block diagram illustrating an example of a gate driver included in the display device of FIG. 1.

FIG. 3 is a circuit diagram illustrating an example of a stage included in the gate driver of FIG. 2.

FIGS. 4, 5A to 5I are diagrams for describing an example in which the gate driver of FIG. 2 is driven.

FIG. 6 is a block diagram illustrating another example of a gate driver included in the display device of FIG. 1.

FIG. 7A is a circuit diagram illustrating an example of a stage included in the gate driver of FIG. 6.

FIG. 7B is a diagram for describing an example in which the gate driver of FIG. 7A is driven.

FIG. 8 is a block diagram illustrating still another example of a gate driver included in the display device of FIG. 1.

FIG. 9 is a circuit diagram illustrating an example of a stage included in the gate driver of FIG. 8.

### DETAILED DESCRIPTION

Hereinafter, aspects of some example embodiments of the present inventive concept will be explained in more detail with reference to the accompanying drawings.

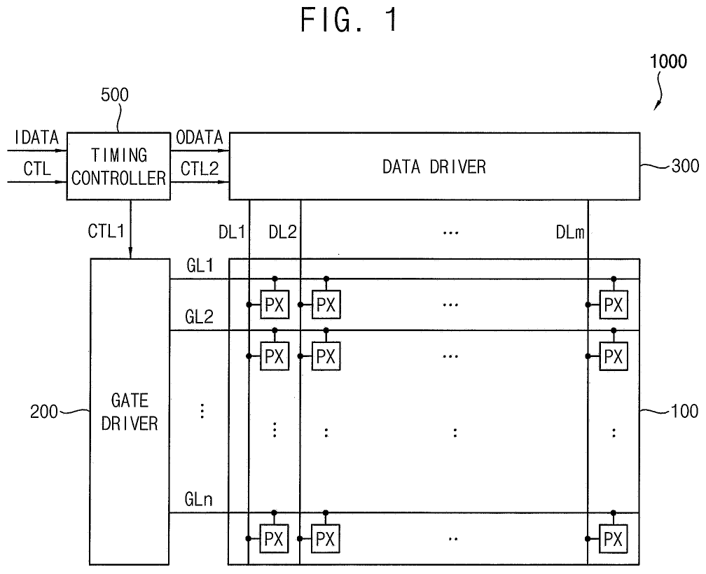

FIG. 1 is a block diagram illustrating a display device according to example embodiments.

Referring to FIG. 1, the display device 1000 may include a display panel 100, a gate driver 200, a data driver 300, and a timing controller 500. In an example embodiment, the display device 1000 may be an organic light emitting display (OLED) device. In this case, the display device 1000 may further include an emission control driver which provides an emission control signal to the display panel 100. In another example embodiment, the display device may be a liquid crystal display (LCD) device. In this case, the display device 1000 may further include a backlight assembly.

The display panel 100 may display an image. The display panel 100 may include a plurality of gate-lines GL1 through GLn, a plurality of data-lines DL1 through DLm, and a plurality of pixels PX. For example, the display panel 100 may include nxm pixels PX arranged at locations corresponding to intersections between the gate-lines GL1 through GLn and the data-lines DL1 through DLm, where n and m are integers greater than 1.

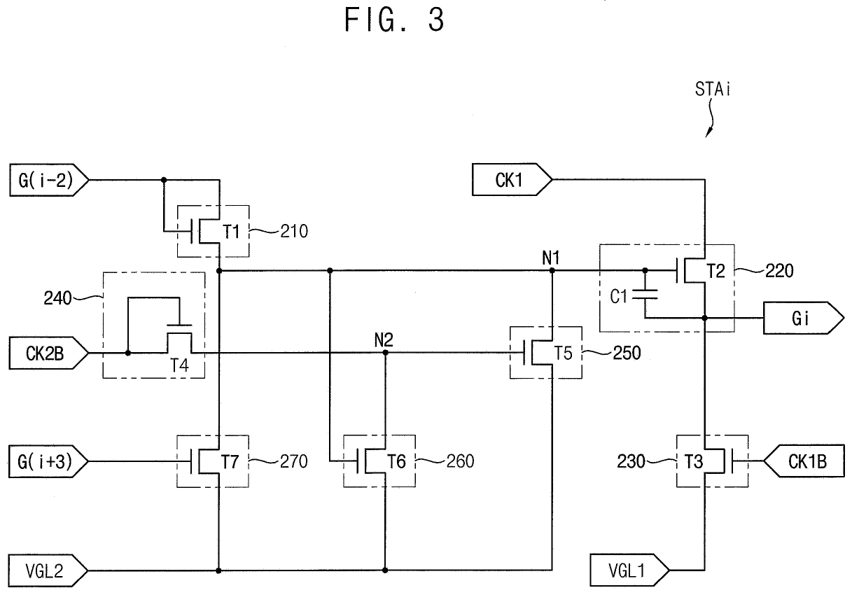

The gate driver 200 may provide the gate signal to the display panel 100 (i.e., the pixels PX) via the gate-lines GL1 through GLn based on a first control signal CTL1. The gate driver 200 may include a plurality of stages each outputting the gate signal as an output signal. For example, the gate driver 200 may include the stages that provide the gate signal to the gate-lines GL1 through GLn. Each of the stages may include a plurality of transistors and a capacitor. In an example embodiment, the stages of the gate driver 200 may be formed (or patterned) on a substrate on which the display panel 100 including the pixels PX is formed (or patterned). Each of the stages of the gate driver 200 may include a first node controlling unit (or first node controller), a first outputting unit (or first outputting circuit), a second outputting unit (or second outputting circuit), a second node controlling unit (or second node controller), a first holding unit (or first holding circuit), a third node controlling unit (or third node controller), and a second holding unit (or second holding circuit). The gate driver 200 may be implemented with a simple circuit in which the first node controlling unit controls a voltage at a first node, the second and third node controlling units control a voltage at a second node, the first and second holding units stabilize the voltage at the first node, and the first and second outputting units output the gate signal based on the voltage at the first node and clock signals. A structure of the stage included in the gate driver 200 will be described in detail with reference to FIGS. 3, 7, and 9.

The data driver 300 may receive a second control signal CTL2 and output image data ODATA. Based on the second control signal CTL2, the data driver 300 may convert the output image data ODATA into a data signal in an analog form and may provide the data signal to the display panel 100 (i.e., the pixels PX) via the data-lines DL1 through DLm.

The timing controller 500 may control the gate driver 200 and the data driver 300. The timing controller 500 may receive input image data DATA and a control signal CTL from an external component (e.g., a system board). The timing controller 500 may generate the first control signal CTL1 and the second control signal CTL2 to control the gate driver 200 and the data driver 300, respectively. For example, the first control signal CTL1 for controlling the gate driver 200 may include a vertical start signal, a gate clock signal, etc. In addition, the second control signal CTL2 for controlling the data driver 300 may include a horizontal start signal, a load signal, etc. The timing controller 500 may generate the output data signal ODATA in a digital form suitable for an operating condition of the display panel 100 based on the input image data DATA and may provide the output data signal ODATA to the data driver 300.

Although it is described above that the gate driver 200 is formed on the substrate on which the display panel 100 is formed, the present inventive concept is not limited thereto. For example, the gate driver 200 may be implemented by a driving chip and may be mounted on (or attached to) the display panel 100 in various ways.

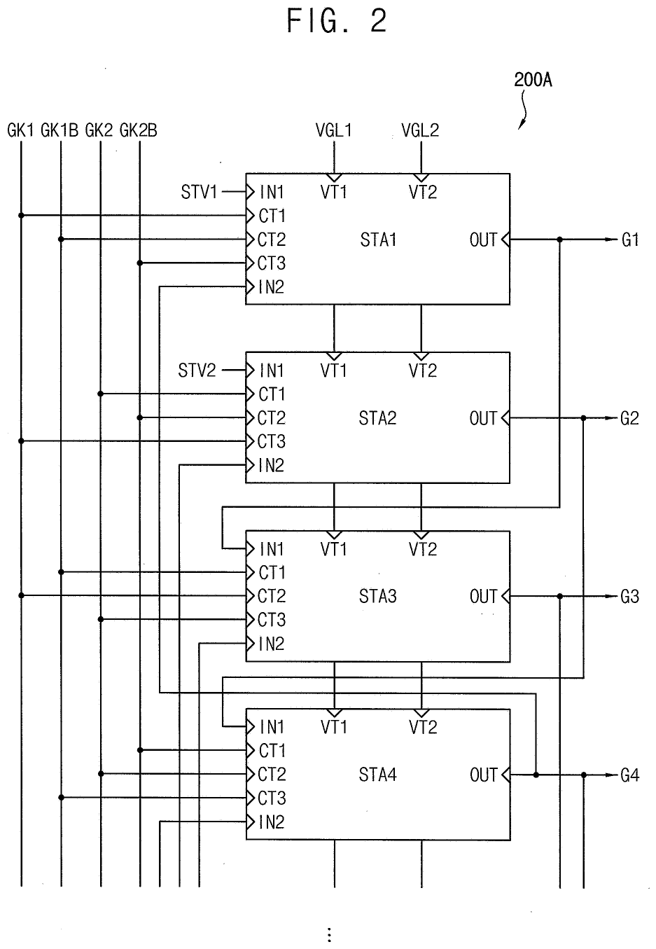

FIG. 2 is a block diagram illustrating an example of a gate driver included in the display device of FIG. 1.

Referring to FIG. 2, the gate driver 200A may include a plurality of stages STA1 through STAn, where n is an integer greater than or equal to 2. Each of the stages STA1 through STAn may include a first input terminal IN1, a second input terminal IN2, a first clock terminal CT1, a second clock terminal CT2, a third clock terminal CT3, a first power terminal VT1, a second power terminal VT2, and an output terminal OUT.

One of a first gate clock signal GK1, a first inverted gate clock signal GK1B, a second gate clock signal GK2, and a second inverted gate clock signal GK2B may be applied to each of the first clock terminal CT1, the second clock terminal CT2, and the third clock terminal CT3 of the stages STA1 through STAn. For example, the first inverted gate clock signal GK1B may be an inverted version of the first gate clock signal GK1. The second gate clock signal GK2 may be a signal which is obtained by shifting the first gate clock signal GK1 by ½ of a horizontal period. The second inverted gate clock signal GK2B may be an inverted version of the second gate clock signal GK2.

The first gate clock signal GK1 may be applied to the first clock terminal CT1 of the (4k−3)th stage (e.g., STA1) as the first clock signal, the first inverted gate clock signal GK1B may be applied to the second clock terminal CT2 of the (4k−3)th stage as the second clock signal, and the second inverted gate clock signal GK2B may be applied to the third clock terminal CT3 of the (4k−3)th stage as the third clock signal, where k is an integer greater than 0. The second gate clock signal GK2 may be applied to the first clock terminal CT1 of the (4k−2)th stage (e.g., STA2) as the first clock signal, the second inverted gate clock signal GK2B may be applied to the second clock terminal CT2 of the (4k−2)th stage as the second clock signal, and the first gate clock signal GK1 may be applied to the third clock terminal CT3 of the (4k−2)th stage as the third clock signal. The first inverted gate clock signal GK1B may be applied to the first clock terminal CT1 of the (4k−1)th stage (e.g., STA3) as the first clock signal, the first gate clock signal GK1 may be applied to the second clock terminal CT2 of the (4k−1)th stage as the second clock signal, and the second gate clock signal GK2 may be applied to the third clock terminal CT3 of the (4k−1)th stage as the third clock signal. The second inverted gate clock signal GK2B may be applied to the first clock terminal CT1 of the (4k)th stage (e.g., STA4) as the first clock signal, the second gate clock signal GK2 may be applied to the second clock terminal CT2 of the (4k)th stage as the second clock signal, and the first inverted gate clock signal GK1B may be applied to the third clock terminal CT3 of the (4k)th stage as the third clock signal.

A vertical start signal or a gate signal of one of previous stages may be applied to the first input terminal IN1 of the stages STA1 through STAn. For example, a first vertical start signal STV1 may be applied to the first input terminal IN1 of the first stage STA1, and a second vertical start signal STV2 may be applied to the first input terminal IN1 of the second stage STA2. Here, the second vertical start signal STV2 may be a signal which is obtained by delaying the first vertical start signal STV1 by ½ of the horizontal period. The gate signal of one of the previous stages may be applied to the first input terminal IN1 of remaining stages STA3 through STAn. For example, the output signal (e.g., the gate signal) of the (i−2)th stage may be applied to the first input terminal IN1 of the (i)th stage. A gate signal of one of next stages may be applied to the second input terminal IN2 of the stages STA1 through STAn, where i is an integer greater than 2. For example, the gate signal of the (i+3)th stage may be applied to the second input terminal IN2 of the (i)th stage. The stages STA1 through STAn may output the gate signals G1 through Gn to the gate-lines at those output terminals OUT. For example, the (i)th stage STAi may output the (i)th gate signal to the (i)th gate-line. The (i)th gate signal may be a signal which is obtained by delaying the (i−1)th gate signal by ½ of the horizontal period.

A first power voltage VGL1 may be applied to a first power terminal VT1 of the stages STA1 through STAn. A second power voltage VGL2 may be applied to a second power terminal VT2 of the stages STA1 through STAn. The first power voltage VGL1 and the second power voltage VGL2 may have an off-level (e.g., a low voltage level). In an example embodiment, the first power voltage VGL1 may be higher than the second power voltage VGL2. For example, the first power voltage VGL1 may be about −6V, and the second power voltage VGL2 may be about −10V.

In an example embodiment, the gate driver 200A may include n stages which output the first through (n)th gates signals to n pixel-rows, respectively. In addition, the gate driver 200A may include dummy stages for generating the first input signal and the second input signal.

Although it is illustrated in FIG. 2 that the gate driver 200A is driven using the first and second scan start signals, the present inventive concept is not limited thereto. For example, the gate driver 200A may be driven using one scan start signal and the dummy stage.

FIG. 3 is a circuit diagram illustrating an example of a stage included in the gate driver of FIG. 2.

Referring to FIG. 3, the (i)th stage STAi of the gate driver 200A may include a first node controlling unit 210, a first outputting unit 220, a second outputting unit 230, a second node controlling unit 240, a first holding unit 250, a third node controlling unit 260, and a second holding unit 270. In an example embodiment, the (i)th stage STAi may output the (i)th gate signal to the (i)th pixel-row via the (i)th gate-line.

The first node controlling unit 210 may receive the output signal of one of the previous stages or the vertical start signal as the first input signal and may apply the first input signal to the first node N1 based on the first input signal. In an example embodiment, the first node controlling unit 210 may include a first transistor T1 including a gate electrode which receives the output signal of the (i−2)th stage (e.g., the (i−2)th gate signal G(i−2)) as the first input signal, a first electrode which receives the first input signal, and a second electrode which is connected to the first node N1. In an example embodiment, the output signal of the (i)th stage may be a signal which is obtained by shifting the first input signal by one horizontal period.

The first outputting unit 220 may apply, based on the voltage at the first node N1, the first clock signal CK1 to the first output terminal at which the (i)th gate signal Gi is output as the output signal. In an example embodiment, the first outputting unit 220 may include a second transistor T2 including a gate electrode which is connected to the first node N1, a first electrode which receives the first clock signal CK1, and a second electrode which is connected to the first output terminal and a first capacitor C1 which is connected between the gate electrode of the second transistor T2 and the second electrode of the second transistor T2.

The second outputting unit 230 may apply, based on the second clock signal CK1B, the first power voltage VGL1 to the first output terminal. In an example embodiment, the second outputting unit 230 may include a third transistor T3 including a gate electrode which receives the second clock signal CK1B, a first electrode which receives the first power voltage VGL1, and a second electrode which is connected to the first output terminal. The second clock signal CK1B may be an inverted version of the first clock signal CK1.

The second node controlling unit 240 may apply, based on the third clock signal CK2B, the third clock signal CK2B to the second node N2. In an example embodiment, the second node controlling unit 240 may include a fourth transistor T4 including a gate electrode which receives the third clock signal CK2B, a first electrode which receives the third clock signal CK2B, and a second electrode which is connected to the second node N2. The third clock signal CK2B may be a signal which is obtained by shifting the second clock signal CK1B by ½ of the horizontal period.

The first holding unit 250 may apply, based on the voltage at the second node N2, the second power voltage VGL2 to the first node N1. In an example embodiment, the first holding unit 250 may include a fifth transistor T5 including a gate electrode which is connected to the second node N2, a first electrode which receives the second power voltage VGL2, and a second electrode which is connected to the first node N1.

The third node controlling unit 260 may apply, based on the voltage at the first node N1, the second power voltage VGL2 to the second node N2. In an example embodiment, the third node controlling unit 260 may include a sixth transistor T6 including a gate electrode which is connected to the first node N1, a first electrode which receives the second power voltage VGL2, and a second electrode which is connected to the second node N2.

The second holding unit 270 may receive the output signal of one of the next stages as the second input signal and may apply, based on the second input signal, the second power voltage VGL2 to the first node N1. In an example embodiment, the second input signal may be a signal which is obtained by shifting the output signal of the (i)th stage by 3/2 of the horizontal period (e.g., the output signal of the (i+3)th stage (i.e., the (i+3)th gate signal G(i+3))). In an example embodiment, the second holding unit 270 may further include a seventh transistor T7 including a gate electrode which receives the second input signal, a first electrode which receives the second power voltage VGL2, and a second electrode which is connected to the first node N1.

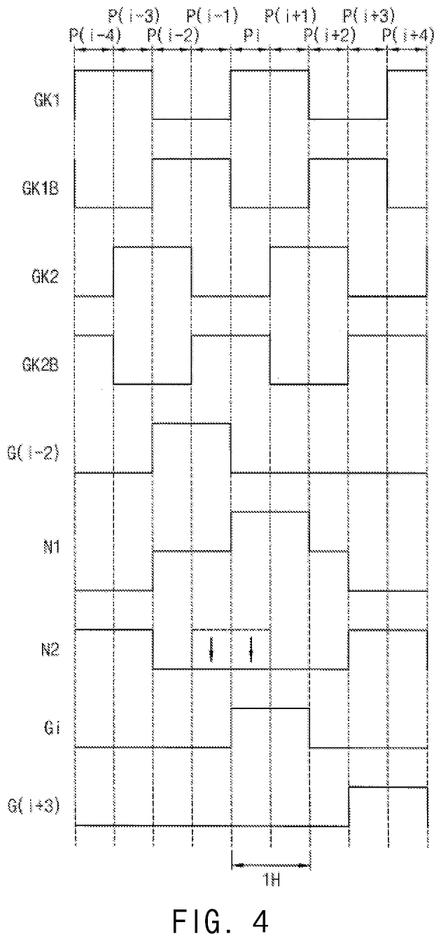

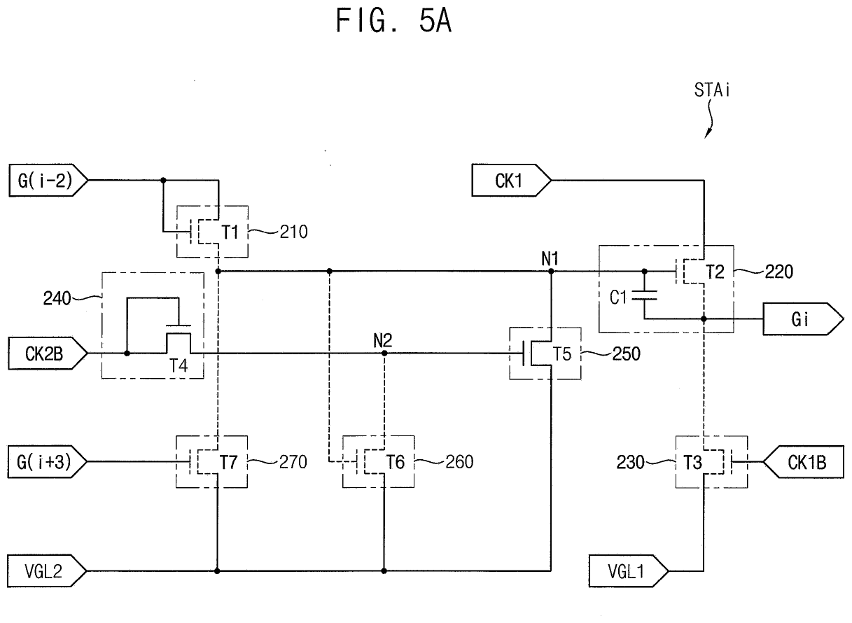

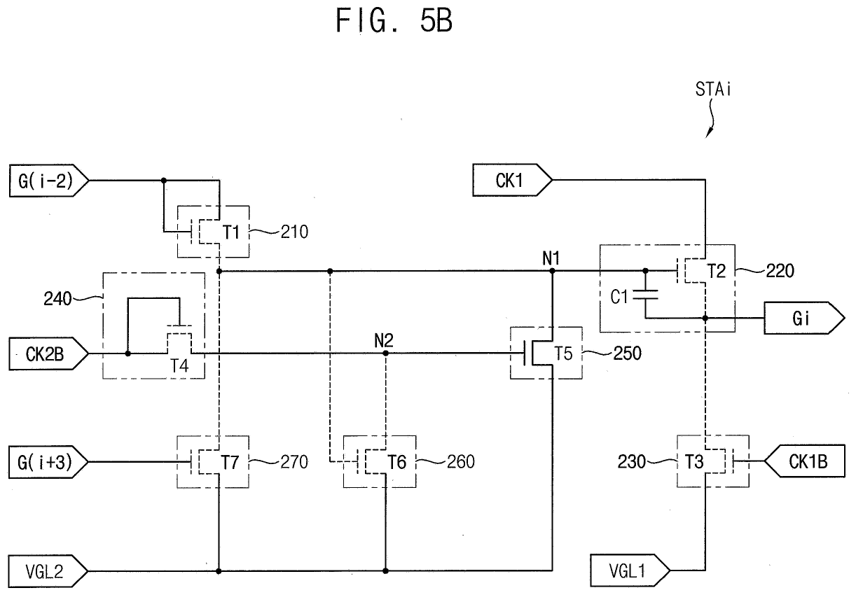

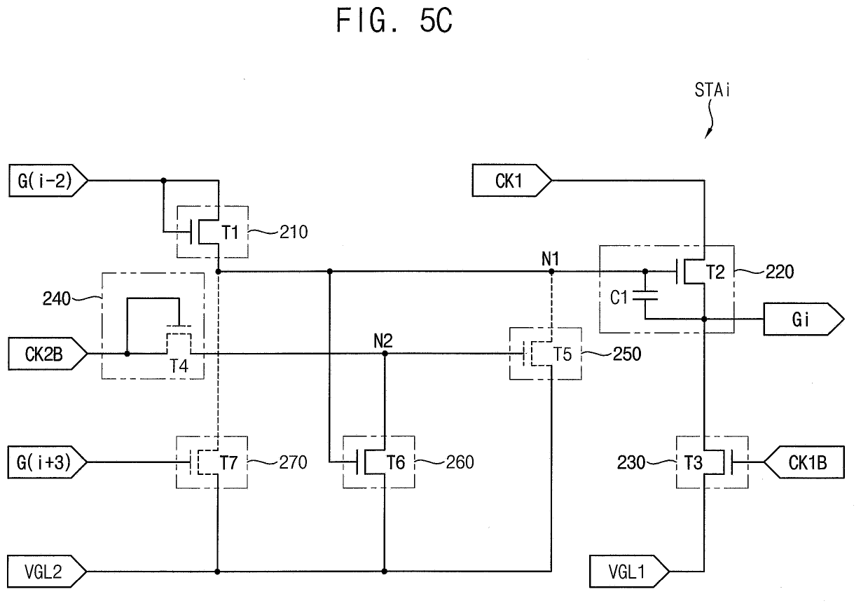

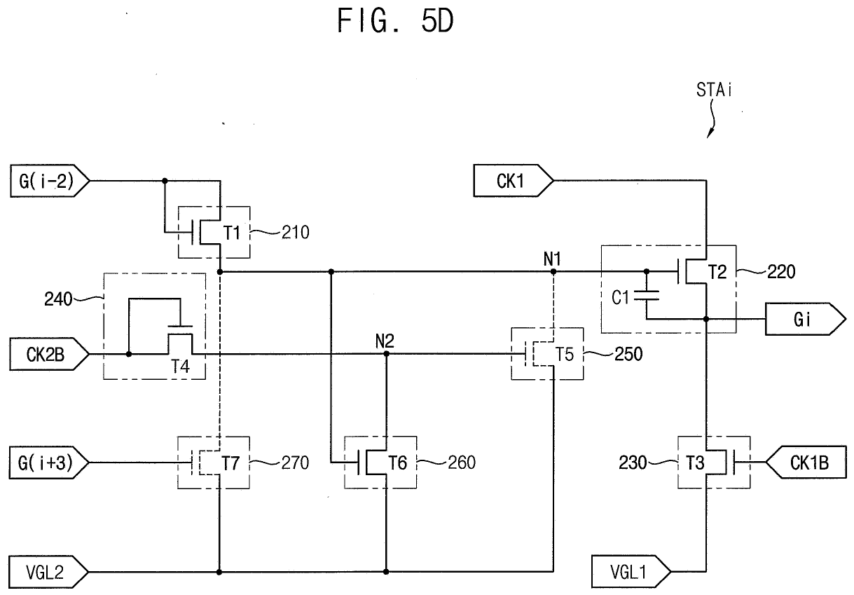

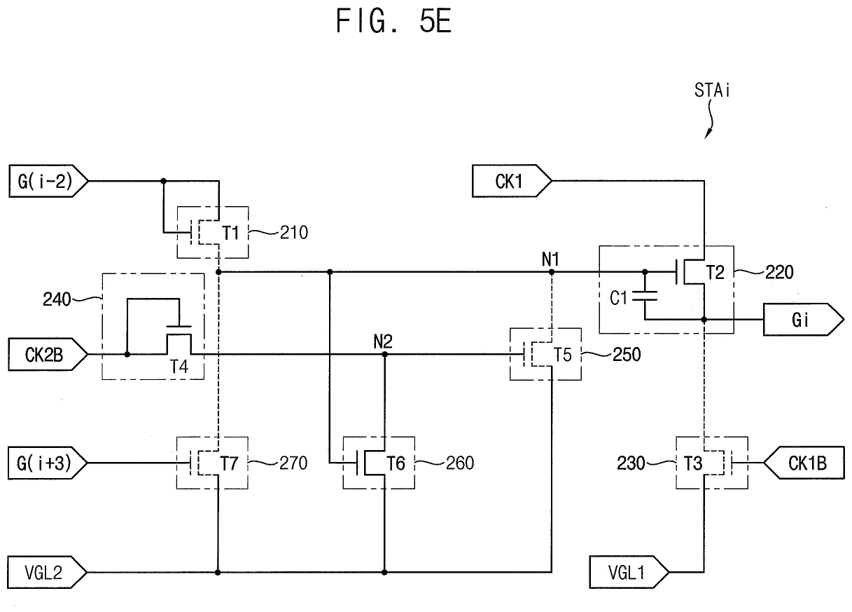

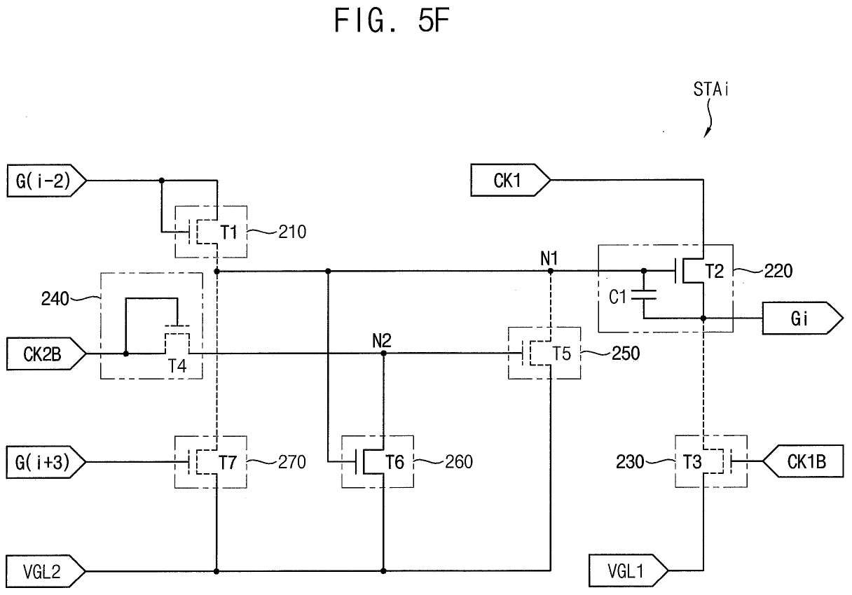

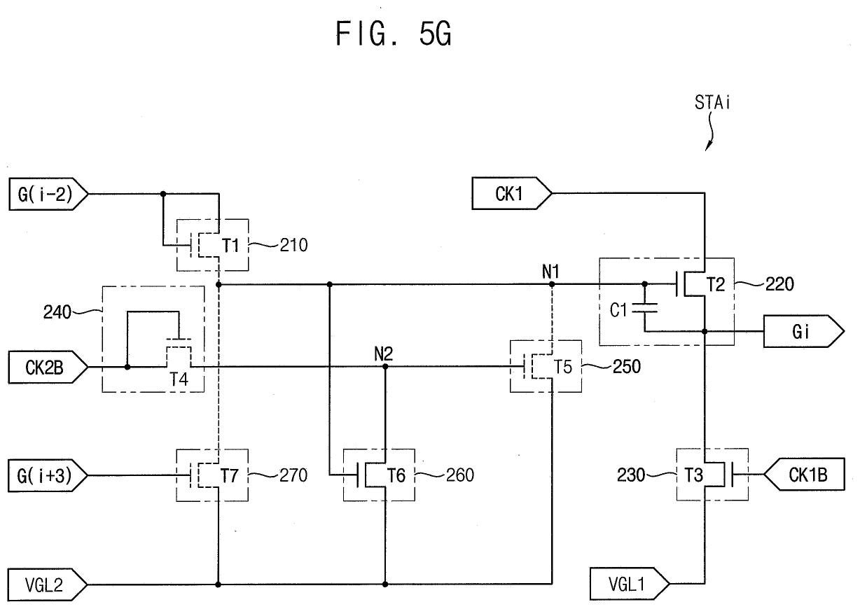

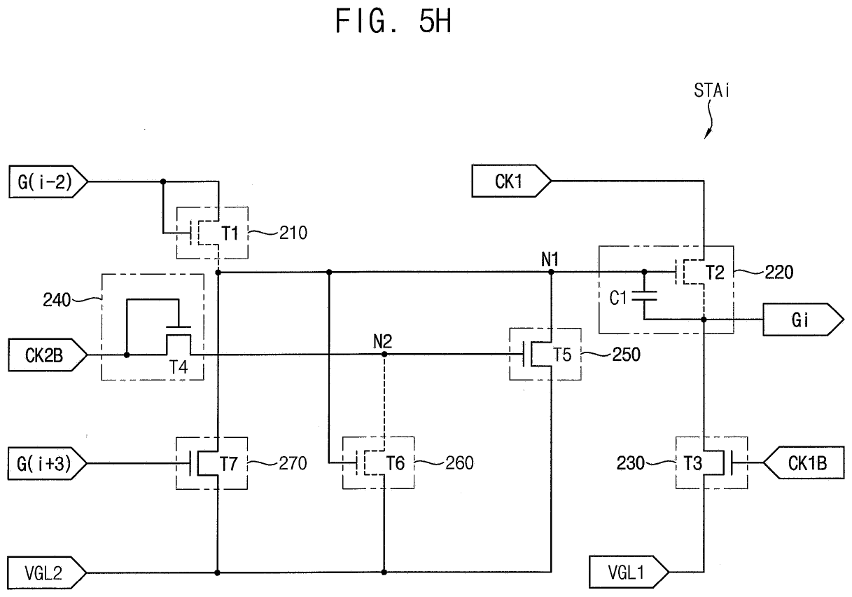

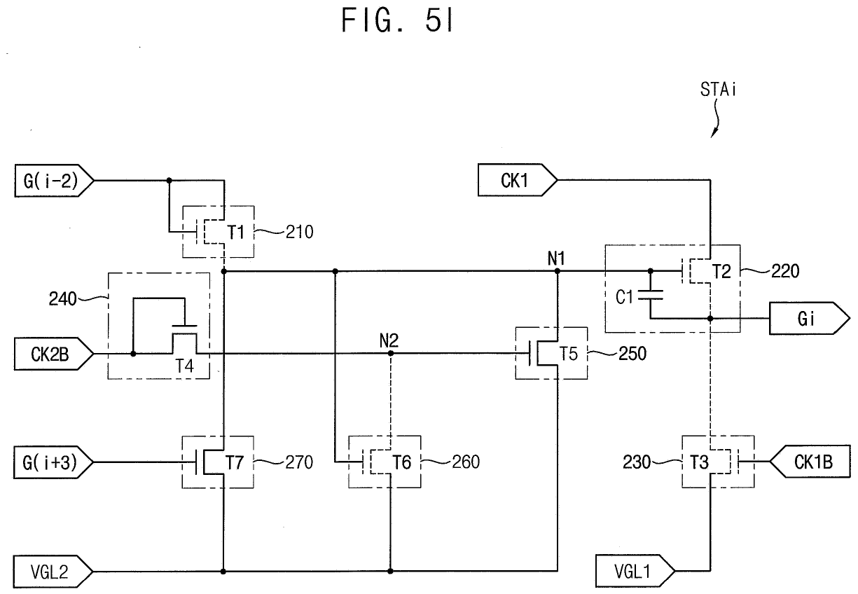

FIGS. 4, 5A to 5I are diagrams for describing an example in which the gate driver of FIG. 2 is driven.

Referring to FIGS. 4, 5A to 5I, the (i)th stage STAi may receive the first gate clock signal GK1 as the first clock signal CK1, the first inverted gate clock signal GK1B as the second clock signal CK1B, the second inverted gate clock signal GK2B as the third clock signal CK2B, the output signal of the (i−2)th stage G(i−2) as the first input signal, and the output signal of the (i+3)th stage G(i+3) as the second input signal.

As illustrated in FIGS. 4 and 5A, the ripple may be caused in the voltage at the first node N1 by a parasitic capacitor which is formed between the gate electrode and the source electrode of the second transistor T2 as the first clock signal CK1 switches to the high voltage level in the (i−4)th period P(i−4). Thus, to maintain the voltage at the first node N1 to have the off-level (e.g., the low voltage level), the fourth transistor T4 may control the voltage at the second node N2 to have an on-level (e.g., the high voltage level) based on the third clock signal CK2B, and the fifth transistor T5 may be turned on. Thus, the fifth transistor T5 may apply the second power voltage VGL2 to the first node N1. As a result, the voltage at the first node N1 may be stabilized to have the off-level quickly.

As illustrated in FIGS. 4 and 5B, the fourth transistor T4 may be turned off as the third clock signal CK2B switches to the low voltage level in the (i−3)th period P(i−3). The second node N2 may be in a floating state, and thus a stored (or charged) voltage of the second node N2 may be maintained for a specific time. Thus, a turn-on state of the fifth transistor T5 may be maintained in the (i−3)th period P(i−3), and the voltage at the first node N1 may be hold to be the second power voltage VGL2.

As illustrated in FIGS. 4 and 5C, the first input signal (i.e., the (i−2)th gate signal G(i−2)) may have the on-level in the (i−2)th period P(i−2), and the voltage at the first node N1 may be pre-charged by the first transistor T1. Because the voltage at the first node N1 is controlled to have the on-level, the sixth transistor T6 may be turned on, and thus the second power voltage VGL2 may be applied to the second node N2. Thus, the voltage at the second node N2 may be controlled to have the off-level, and thus the fifth transistor T5 may be turned off.

As illustrated in FIGS. 4 and 5D, the fourth transistor T4 may be turned on as the third clock signal CK2B switches to the high voltage level in the (i−1)th period P(i−1). In addition, because the voltage at the first node N1 has the on-level, the sixth transistor T6 may be turned on. Because the second power voltage VGL2 is applied to the second node N2 (i.e., the voltage at the second node N2 is controlled to have the off-level) in the (i−2)th period P(i−2) and the (i−1)th period P(i−1), the fifth transistor T5 may not be turned on even when the fourth transistor T4 is turned on as the third clock signal CK2B switches to the high voltage level in the (i−1)th period P(i−1). That is, a conventional inverter function may be performed by the operation. Because the fourth transistor T4 and the sixth transistor T6 may be concurrently turned on, the voltage at the second node N2 may be determined by aspect ratios of the fourth transistor T4 and the sixth transistor T6. Here, the aspect ratio denotes a ratio of a channel length to a channel width. A first aspect ratio of the sixth transistor T6 may be larger than a second aspect ratio of the fourth transistor T4 so that the fifth transistor T5 may be turned off. For example, a ratio of the first aspect ratio to the second aspect ratio may be set to be about 5:3 so that a voltage difference between the gate electrode and the source electrode of the fifth transistor T5 may be close to 0V.

As illustrated in FIGS. 4 and 5E, the voltage at the first node N1 may be boosted by the first capacitor C1 as the first clock signal CK1 switches to the high voltage level in the (i)th period Pi. The second transistor T2 may be turned on, and the first clock signal CK1 having the on-level may be output as the output signal (i.e., the (i)th gate signal Gi). In addition, to prevent the voltage at the first node N1 from being decreased, the sixth transistor T6 may be turned on, the voltage at the second node N2 may be maintained to have the off-level, and the fifth transistor T5 may be turned off.

As illustrated in FIGS. 4 and 5F, the fourth transistor T4 may be turned off as the third clock signal CK2B switches to the low voltage level in the (i+1)th period P(i+1). The voltage at the second node N2 may be maintained to have the off-level by the sixth transistor T6, and the voltage at the first node N1 may be maintained to have the boosted voltage level. Thus, the first clock signal CK1 having the on-level may be output as the first gate signal Gi during one horizontal period 1H corresponding to the (i)th period Pi and the (i+1)th period P(i+1).

As illustrated in FIGS. 4 and 5G, in the (i+2)th period P(i+2), the first clock signal CK1 may switch to the low voltage level, and the second clock signal CK1B may switch to the high voltage level. Thus, the third transistor T3 may be turned on, and the first power voltage VGL1 having the off-level may be output as the (i)th gate signal Gi. In addition, because the voltage at the first node Ni has the on-level, a turn-on state of the second transistor T2 may be maintained, and the first clock signal CK1 having the off-level may be output as the (i)th gate signal Gi.

As illustrated in FIGS. 4 and 5H, in the (i+3)th period P(i+3), the second input signal having the on-level (i.e., the (i+3)th gate signal G(i+3)) may be applied to the seventh transistor T7, and thus the seventh transistor T7 may be turned on. In addition, as the third clock signal CK2B switches to the high voltage level, the fourth transistor T4 may control the voltage at the second node N2 to have the on-level, and thus the fifth transistor T5 may be turned on. Thus, the second power voltage VGL2 having the off-level may be applied to the first node N1 by the fifth transistor T5 and the seventh transistor T7. As a result, the voltage at the first node N1 may be controlled to have the off-level, and thus the second transistor T2 may be turned off.

When the second input signal corresponds to the (i+2)th gate signal G(i+2), the first node N1 having the boosted voltage level in the (i+2)th period P(i+2) may be controlled to have the off-level by the seventh transistor T7. In this case, because a voltage difference between both electrodes (i.e., the source electrode and the drain electrode) of the seventh transistor T7 is relatively large, the seventh transistor T7 may be easily deteriorated. On the other hand, when the second input signal is the (i+3)th gate signal G(i+3) like this embodiment, the first node N1 of which the voltage is relatively low by discharging in the (i+3)th period P(i+3) may be controlled to have the off-level by the fifth transistor T5 and the seventh transistor T7. Thus, loads of the fifth and seventh transistors T5 and T7 may be reduced, and thus deterioration the fifth and seventh transistors T5 and T7 may be prevented or reduced.

In an example embodiment, the first power voltage VGL1 may have the off-level, the second power voltage VGL2 may have the off-level, and the first power voltage VGL1 may be higher than the second power voltage VGL2. In the (i+3)th period P(i+3), the second power voltage VGL2 may be applied to the gate electrode of the second transistor T2 by the fifth and seventh transistors T5 and T7 which are turned on, and the first power voltage VGL1 may be applied to the second electrode of the second transistor T2 by the third transistor which is turned on. That is, when the second power voltage VGL2 is applied to the gate electrode of the second transistor T2, the first power voltage VGL1 which is higher than the second power voltage VGL2 may be applied to the second electrode of the second transistor T2. Thus, a leakage current flowing from the first electrode of the second transistor T2 to the second electrode of the second transistor T2 may be prevented or reduced.

As illustrated in FIGS. 4 and 5I, like the (i−4)th period P(i−4), the ripple may be caused in the voltage at the first node N1 by the parasitic capacitor which is formed between the gate electrode and the source electrode of the second transistor T2 as the first clock signal CK1 switches to the high voltage level in the (i+4)th period P(i+4). However, because the fifth transistor T5 is already turned on by the third clock signal CK2B, the voltage at the first node N1 may be stabilized to the second power voltage VGL2 quickly although a noise enters.

In brief, the gate driver 200A may be implemented by a simple circuit in which the fifth transistor T5 which holds the first node N1 is controlled based on the voltage at the second node N2 and the voltage at the second node N2 is controlled by the fourth transistor T4 and the sixth transistor T6 based on the third clock signal CK2B and the voltage at the first node N1, respectively. The gate driver 200A may prevent or reduce the leakage current by separating the voltage having the off-level from the first power voltage VGL1 and the second power voltage VGL2. In addition, the gate driver 200A may reduce the deterioration of the fifth and seventh transistors T5 and T7 by including the seventh transistor T7 which is controlled based on the second input signal (i.e., the gate signal of the (i+3)th stage).

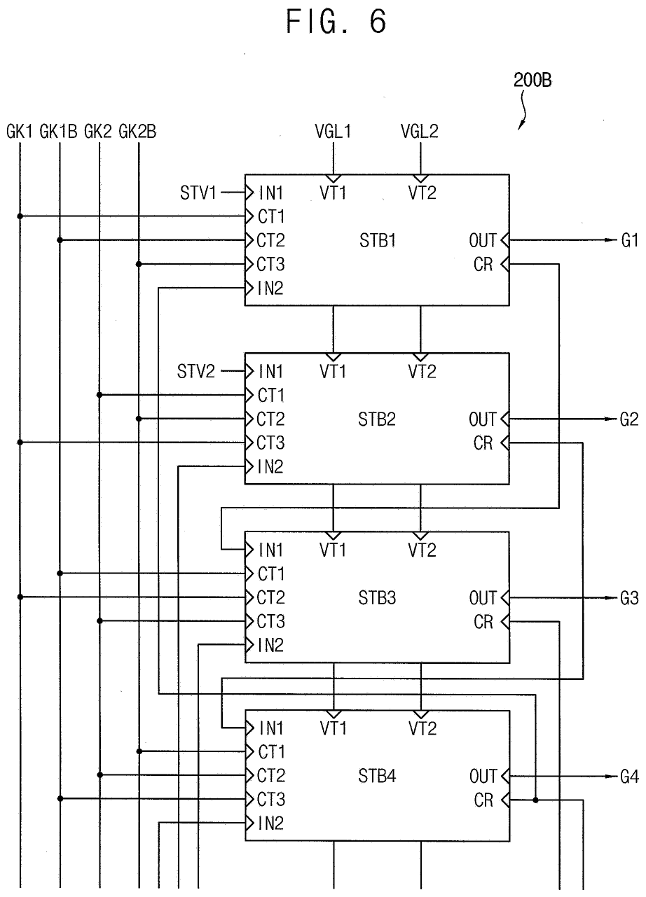

FIG. 6 is a block diagram illustrating another example of a gate driver included in the display device of FIG. 1.

Referring to FIG. 6, the gate driver 200B may include a plurality of stages STB1 through STBn. Each of the stages STB1 through STBn may include a first input terminal IN1, a second input terminal IN2, a first clock terminal CT1, a second clock terminal CT2, a third clock terminal CT3, a first power terminal VT1, a second power terminal VT2, an output terminal OUT, and a carry terminal CR. Except that each of the stages STB1 through STBn of the gate driver 200B further includes the carry terminal CR, the gate driver 200B may be substantially the same as the gate driver 200A of FIG. 2. Thus, the same reference numerals will be used for the same or similar components, and duplicated description will not be repeated.

A vertical start signal or a carry signal of one of previous stages may be applied to the first input terminal IN1 of the stages STB1 through STBn. For example, a first vertical start signal STV1 may be applied to the first input terminal IN1 of the first stage STB1, a second vertical start signal STV2 may be applied to the first input terminal IN1 of the second stage STB2, and the carry signal of one of the previous stages may be applied to the first input terminal IN1 of remaining stages STB3 through STBn. For example, the output signal (e.g., the carry signal) of the (i−2)th stage may be applied to the first input terminal IN1 of the (i)th stage. A carry signal of one of next stages may be applied to the second input terminal IN2 of the stages STB1 through STBn. For example, the carry signal of the (i+3)th stage may be applied to the second input terminal IN2 of the (i)th stage. The stages STB1 through STBn may output the gate signals G1 through Gn to the gate-lines at those output terminals OUT. The stages STB1 through STBn may output the carry signals at those carry terminals CR.

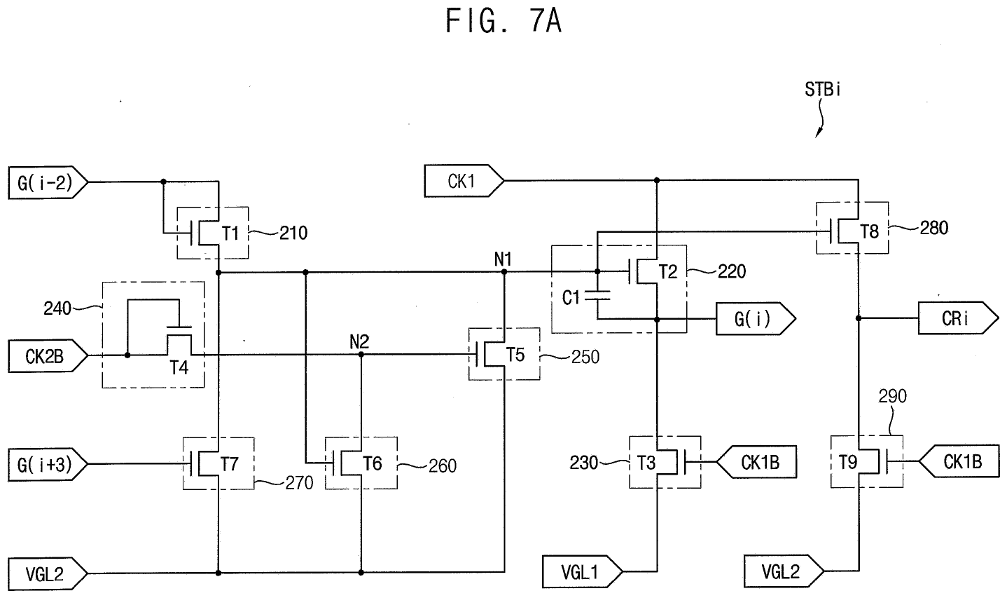

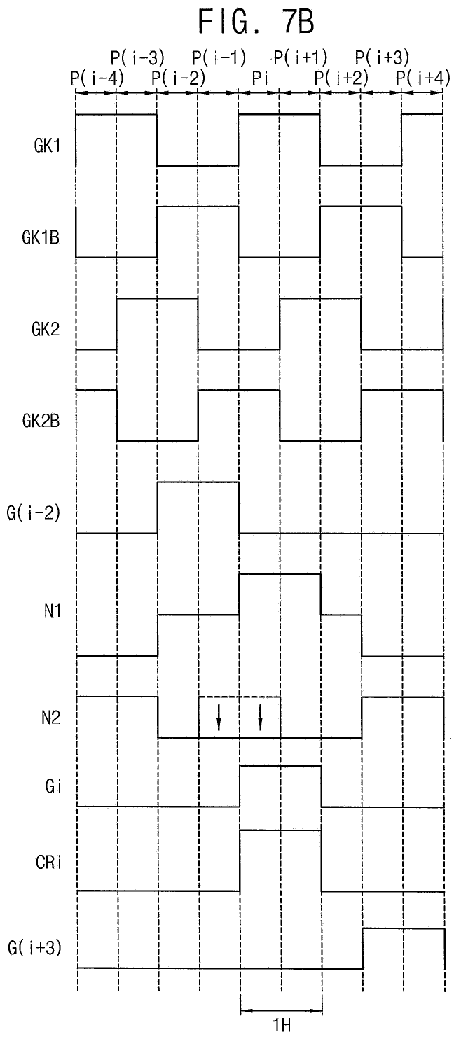

FIG. 7A is a circuit diagram illustrating an example of a stage included in the gate driver of FIG. 6, and FIG. 7B is a diagram for describing an example in which the gate driver of FIG. 7A is driven.

Referring to FIGS. 7A and 7B, the (i)th stage STBi of the gate driver 200B may include a first node controlling unit 210, a first outputting unit 220, a second outputting unit 230, a second node controlling unit 240, a first holding unit 250, a third node controlling unit 260, a second holding unit 270, a first carry outputting unit (or first carry outputting circuit) 280, and a second carry outputting unit (or second carry outputting circuit) 290. The (i)th stage STBi may output the gate signal to the (i)th pixel-row via the (i)th gate-line. Except that the stage STBi further includes the first and second carry outputting units 280 and 290, the stage STBi may be substantially the same as the stage STAi of FIG. 3. Thus, the same reference numerals will be used for the same or similar components, and duplicated description will not be repeated.

The first node controlling unit 210 may receive the output signal of one of the previous stages or the vertical start signal as the first input signal and may apply the first input signal to the first node N1 based on the first input signal.

The first outputting unit 220 may apply, based on the voltage at the first node N1, the first clock signal CK1 to the first output terminal at which the (i)th gate signal Gi is output as the output signal.

The second outputting unit 230 may apply, based on the second clock signal CK1B, the first power voltage VGL1 to the first output terminal.

The second node controlling unit 240 may apply, based on the third clock signal CK2B, the third clock signal CK2B to the second node N2.

The first holding unit 250 may apply, based on the voltage at the second node N2, the second power voltage VGL2 to the first node N1.

The third node controlling unit 260 may apply, based on the voltage at the first node N1, the second power voltage VGL2 to the second node N2.

The second holding unit 270 may receive the output signal of one of the next stages as the second input signal and may apply, based on the second input signal, the second power voltage VGL2 to the first node N1.

The first carry outputting unit 280 may apply, based on the voltage at the first node N1, the first clock signal CK1 to the second output terminal at which the (i)th carry signal is output as the output signal. In an example embodiment, the first carry outputting unit 280 may include an eighth transistor T8 including a gate electrode which is connected to the first node N1, a first electrode which receives the first clock signal CK1, and a second electrode which is connected to the second output terminal.

The second carry outputting unit 290 may apply, based on the second clock signal CK1B, the second power voltage VGL2 to the second output terminal. In an example embodiment, the second carry outputting unit 290 may include a ninth transistor T9 including a gate electrode which receives the second clock signal CK1B, a first electrode which receives the second power voltage VGL2, and a second electrode which is connected to the second output terminal.

The (i)th stage STBi may output the gate signal Gi and the carry signal CRi. The (i)th stage STBi may use the carry signal CRi instead of the gate signal Gi as the first input signal of the next stage or the second input signal of the previous stage. Thus, the (i)th stage STBi may reduce a rising time and a falling time of the gate signal Gi and may stably output the gate signal Gi. Here, because the carry signal CRi is used as the first input signal of one of the next stages and/or the second input signal of one of the previous stages, sizes of the eighth and ninth transistors T8 and T9 may be smaller than sizes of the second and third transistors T2 and T3.

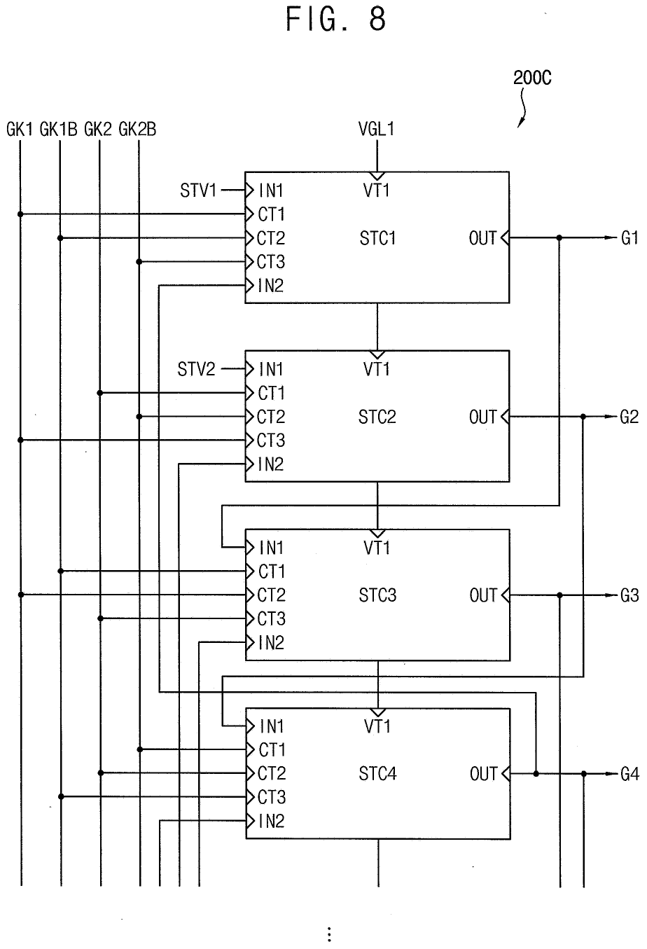

FIG. 8 is a block diagram illustrating still another example of a gate driver included in the display device of FIG. 1.

Referring to FIG. 8, the gate driver 200C may include a plurality of stages STC1 through STCn. Each of the stages STC1 through STCn may include a first input terminal IN1, a second input terminal IN2, a first clock terminal CT1, a second clock terminal CT2, a third clock terminal CT3, a first power terminal VT1, and an output terminal OUT. Except that each of the stages STC1 through STCn of the gate driver 200C does not include the second power terminal VT2, the gate driver 200C may be substantially the same as the gate driver 200A of FIG. 2. Thus, the same reference numerals will be used for the same or similar components, and duplicated description will not be repeated.

A first power having the first power voltage VGL1 may be provided to the first power terminal VT1 of the stages STC1 through STCn. For example, the first power voltage VGL1 may have the off-level (e.g., the low voltage level).

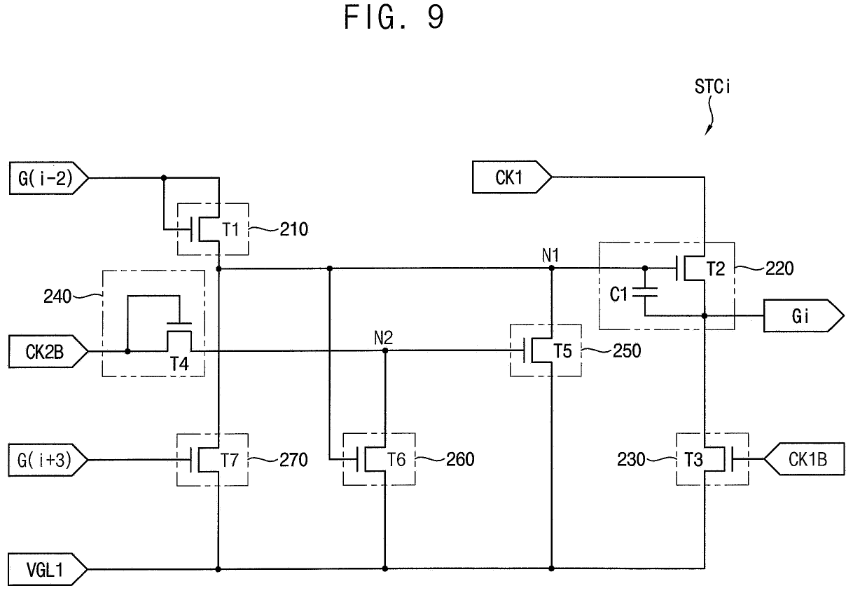

FIG. 9 is a circuit diagram illustrating an example of a stage included in the gate driver of FIG. 8.

Referring to FIG. 9, the (i)th stage STCi of the gate driver 200C may include a first node controlling unit 210, a first outputting unit 220, a second outputting unit 230, a second node controlling unit 240, a first holding unit 250, a third node controlling unit 260, and a second holding unit 270. Except that the stage STCi uses only the first power voltage VGL1 as a voltage having the off-level to reduce the number of power voltages, the stage STCi may be substantially the same as the stage STAi of FIG. 3. Thus, the same reference numerals will be used for the same or similar components, and duplicated description will not be repeated.

The first node controlling unit 210 may receive the output signal of one of the previous stages or the vertical start signal as the first input signal and may apply the first input signal to the first node N1 based on the first input signal.

The first outputting unit 220 may apply, based on the voltage at the first node N1, the first clock signal CK1 to the first output terminal at which the (i)th gate signal Gi is output as the output signal.

The second outputting unit 230 may apply, based on the second clock signal CK1B, the first power voltage VGL1 to the first output terminal.

The second node controlling unit 240 may apply, based on the third clock signal CK2B, the third clock signal CK2B to the second node N2.

The first holding unit 250 may apply, based on the voltage at the second node N2, the first power voltage VGL1 to the first node N1.

The third node controlling unit 260 may apply, based on the voltage at the first node N1, the first power voltage VGL1 to the second node N2.

The second holding unit 270 may receive the output signal of one of the next stages as the second input signal and may apply, based on the second input signal, the first power voltage VGL1 to the first node N1.

In brief, the second outputting unit 230, the first holding unit 250, the third node controlling unit 260, and the second holding unit 270 may receive the first power voltage VGL1. When a leakage current does not occur in the second transistor T2 or when reliability of the gate signal is secured, the off-level may be set using only the first power voltage VGL1. In this case, a lighter weight display device may be implemented.

Although a gate driver and a display device including the gate driver according to example embodiments have been described with reference to figures, those skilled in the art will readily appreciate that many modifications are possible in the example embodiments without materially departing from the novel teachings and aspects of the present inventive concept. For example, although it is described above that transistors included in stages are implemented by n-channel metal oxide semiconductor (NMOS) transistors, types of the transistors are not limited thereto. For example, the transistors may be implemented by p-channel metal oxide semiconductor (PMOS) transistors.

The present inventive concept may be applied to an electronic device including a display device. For example, the present inventive concept may be applied to a computer, a laptop, a cellular phone, a smart phone, a smart pad, a portable multimedia player (PMP), a personal digital assistant (PDA), an MP3 player, a digital camera, a video camcorder, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and aspects of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims, and their equivalents.

What is claimed is:

1. A gate driver comprising:
a plurality of stages each configured to output an output signal,
wherein an (i)th stage (i being a natural number) of the stages comprises:
a first transistor including a gate electrode configured to receive an output signal of one of previous stages or a vertical start signal as a first input signal, a first electrode configured to receive the first input signal, and a second electrode connected to a first node;
a second transistor including a gate electrode connected to the first node, a first electrode configured to receive a first clock signal, and a second electrode connected to a first output terminal;
a third transistor including a gate electrode configured to receive a second clock signal that is inverted with respect to the first clock signal, a first electrode configured to receive a first power voltage, and a second electrode connected to the first output terminal;
a fourth transistor including a gate electrode configured to receive a third clock signal, a first electrode configured to receive the third clock signal, and a second electrode connected to a second node;
a fifth transistor including a gate electrode connected to the second node, a first electrode configured to receive a second power voltage lower than the first power voltage, and a second electrode connected to the first node;
a sixth transistor including a gate electrode connected to the first node, a first electrode configured to receive the second power voltage such that the first electrode of the fifth transistor and the first electrode of the sixth transistor are configured to receive the second power voltage that is lower than the first power voltage applied to the first electrode of the third transistor, and a second electrode connected to the second node; and
a seventh transistor including a gate electrode configured to receive an output signal of an (i+3)th stage of the stages as a second input signal, a first electrode configured to receive the second power voltage, and a second electrode connected to the first node.

2. The gate driver of claim 1, wherein the output signal of a next stage is a signal which is obtained by shifting the output signal of each of the stages by 3/2 of one horizontal period.

3. The gate driver of claim 1, wherein a first aspect ratio of the sixth transistor is larger than a second aspect ratio of the fourth transistor.

4. The gate driver of claim 1, wherein each of the stages further comprises:
a first capacitor connected between the gate electrode of the second transistor and the second electrode of the second transistor.

5. The gate driver of claim 1, wherein the third clock signal is a signal which is obtained by shifting the second clock signal by ½ of one horizontal period.

6. The gate driver of claim 1, wherein the output signal of each of the stages is a signal which is obtained by shifting the output signal of a previous stage by one horizontal period.

7. The gate driver of claim 1, wherein each of the stages further comprises:
an eighth transistor including a gate electrode connected to the first node, a first electrode configured to receive the first clock signal, and a second electrode connected to a second output terminal; and
a ninth transistor including a gate electrode configured to receive the second clock signal, a first electrode configured to receive the second power voltage, and a second electrode connected to the second output terminal.

8. A gate driver comprising:
a plurality of stages each configured to output an output signal,
wherein an (i)th stage (i being a natural number) of the stages comprises:
a first node controller configured to receive an output signal of one of previous stages or a vertical start signal as a first input signal and to apply the first input signal to a first node based on the first input signal;
a first outputting circuit configured to apply a first clock signal to a first output terminal based on a voltage at the first node;
a second outputting circuit configured to apply a first power voltage to the first output terminal based on a second clock signal that is inverted with respect to the first clock signal;
a second node controller configured to apply a third clock signal to a second node based on the third clock signal;
a first holding circuit configured to apply a second power voltage lower than the first power voltage to the first node based on a voltage at the second node;
a third node controller configured to apply the second power voltage to the second node based on the voltage at the first node such that the first node and the second node are configured to receive the second power voltage that is lower than the first power voltage applied to the first output terminal; and
a second holding circuit configured to receive an output signal of an (i+3)th stage of the stages as a second input signal and to apply the second power voltage to the first node based on the second input signal.

9. The gate driver of claim 8, wherein the output signal of a next stage is a signal which is obtained by shifting the output signal of each of the stages by 3/2 of one horizontal period.

10. The gate driver of claim 8, wherein a first aspect ratio of a transistor included in the third node controller is larger than a second aspect ratio of a transistor included in the second node controller.

11. The gate driver of claim 8, wherein each of the stages further comprises:
a first carry outputting circuit configured to apply the first clock signal to a second output terminal based on the voltage at the first node; and
a second carry outputting circuit configured to apply the second power voltage to the second output terminal based on the second clock signal.

12. A display device comprising:
a display panel including a plurality of gate-lines, a plurality of data-lines, and a plurality of pixels;
a data driver configured to provide a data signal to the pixels via the data-lines; and
a gate driver configured to provide a gate signal to the pixels via the gate-lines, the gate driver including a plurality of stages each configured to output the gate signal as an output signal,
wherein an (i)th stage of the stages comprises:
a first transistor including a gate electrode configured to receive an output signal of one of previous stages or a vertical start signal as a first input signal, a first electrode configured to receive the first input signal, and a second electrode connected to a first node;
a second transistor including a gate electrode connected to the first node, a first electrode configured to receive a first clock signal, and a second electrode connected to a first output terminal;
a third transistor including a gate electrode configured to receive a second clock signal that is inverted with respect to the first clock signal, a first electrode configured to receive a first power voltage, and a second electrode connected to the first output terminal;
a fourth transistor including a gate electrode configured to receive a third clock signal, a first electrode configured to receive the third clock signal, and a second electrode connected to a second node;
a fifth transistor including a gate electrode connected to the second node, a first electrode configured to receive a second power voltage lower than the first power voltage, and a second electrode connected to the first node;
a sixth transistor including a gate electrode connected to the first node, a first electrode configured to receive the second power voltage such that the first electrode of the fifth transistor and the first electrode of the sixth transistor are configured to receive the second power voltage that is lower than the first power voltage applied to the first electrode of the third transistor, and a second electrode connected to the second node; and
a seventh transistor including a gate electrode configured to receive an output signal of an (i+3)th stage of the stages as a second input signal, a first electrode configured to receive the second power voltage, and a second electrode connected to the first node.

13. The display device of claim 12, wherein the output signal of a next stage is a signal which is obtained by shifting the output signal of each of the stages by 3/2 of one horizontal period.

14. The display device of claim 12, wherein a first aspect ratio of the sixth transistor is larger than a second aspect ratio of the fourth transistor.
